(19) United States
(12) Patent Application Publication
(10) Pub. No.: US 2006/0244124 A1
(43) Pub. Date: Nov. 2, 2006

(54) Reduced cost printed circuit board

(75) Inventor: Anders Ingemar Ohlsson, Sundbyberg (SE)

Correspondence Address: BLANK ROME LLP, 600 NEW HAMPSHIRE AVENUE, N.W., WASHINGTON, DC, 20037, US

(73) Assignee: Teradyne, Inc., Boston, MA (US)

(21) Appl. No.: 11/115,874

(22) Filed: Apr. 27, 2005

(51) Int. Cl. H01L 23/52; H01L 21/48

(52) U.S. Cl. 257/700; 257/691; 257/692; 438/125

(57) ABSTRACT

A printed circuit board in which signal traces are not restricted in orientation based on the orientation of traces in an adjacent layer. Spacing between layers is increased to reduce crosstalk, which keeps the crosstalk at acceptable levels even when traces on adjacent layers are routed with similar orientations. Spacing between signal traces and ground is reduced to allow signal traces to be placed closer together, thereby increasing the number of traces that can be placed within routing channels. In a backplane or other structure in which more signal traces must be routed in one direction than an other, these differences from traditional design practices, either alone or in combination, decreases the total number of layers needed to route signal traces, which can reduce the cost of manufacturing the printed circuit board.

### 1. FIELD OF THE INVENTION

This invention relates generally to electronic systems and more particularly to printed circuit boards used in electronic systems.

### 2. DISCUSSION OF RELATED ART

Printed circuit boards are used in many electronic systems. The printed circuit board contains many traces that carry electrical signals between components of the system. Holes or “vias” are made through the printed circuit board, allowing connections between traces inside the printed circuit board and components attached to the board.

Many printed circuit boards contain active electronic components, such as integrated circuit chips. Such printed circuit boards are often called “daughter cards.” Some printed circuit boards are used predominantly to route signals between daughter cards. Such printed circuit boards are sometimes called “backplanes.” Rather than containing large numbers of active electronic components, backplanes often contain many electrical connectors. These electrical connectors mate with electrical connectors on the daughter cards so that the signal traces in the backplane may route signals between daughter cards in the system. Often, backplanes contain numerous traces to allow for routing all of the necessary signals between daughter cards.

Printed circuit boards are traditionally manufactured in layers. Each layer contains conductive material, often copper, that is patterned. On some layers, called signal layers, the conductive material is patterned to make signal traces. On other layers, called reference layers, the conductive material is patterned to make ground planes. Insulative material, sometimes called the “matrix,” separates the conductors on different layers.

To make a printed circuit board carrying many signals, such as a backplane, multiple layers are used. As the printed circuit board is being designed, if more signals must pass through the printed circuit board than can fit on the number of layers in the design, additional layers must be added to the design.

During manufacture of the printed circuit board, a structure called a “core” is often used. The core contains a sheet of matrix material that may have either no metal coating or a metal coating on one or a metal coating on two sides. Each metal coating is patterned, typically using photolithography and etching, to create the desired pattern of either signal traces or a ground plane for one layer of the printed circuit board. To assemble a printed circuit board, the patterned cores are stacked up. The entire stack of cores is then heated under pressure. As a result, the matrix material in the cores fuses to create an integral structure. Holes are then drilled through the board and plated with a conductive material to create vias between the layers.

FIG. 1 shows a printed circuit board 100 such is known in the art. Printed circuit board 100 is greatly simplified. Only two vias 132 and 134 are shown, but a printed circuit board such as may be used in a commercially available electronic system may have hundreds or thousands of vias. Similarly, a relatively small number of signal traces are illustrated in connection with printed circuit board 100, but a printed circuit board as used in a commercially available electronic system may have many more signal traces.

Printed circuit board 100 is shown to be made of cores 112, 116, 118, 120, 124, and 126. Core 112 has a ground plane 114 formed on an upper surface. Core 116 acts as a spacer and does not have conductive structures formed on either surface.

Core 118 has signal traces formed on both sides. Pairs of signal traces 1401, 1402, and 1403 are formed on a lower surface of core 118. Pairs of signal traces 150, and 1502, are formed on the upper surface of core 118. The traces are formed in pairs to facilitate transmission of differential signals.

Core 120 has a ground plane 122 formed on its upper surface. Core 124 serves as a spacer and does not have conductors formed on either surface.

Core 126 contains pairs of signal traces 1421, 1422, and 1423 on its lower surface and pairs, of signal traces 1521, and 1522 on its upper surface.

Printed circuit board 100 may be extended to include more layers and therefore more signal traces by adding cores. The number of layers in a printed circuit board is often driven by the number of signal traces required and constraints on the size and spacing of traces that limit the number of traces that may be routed on one layer.

In designing a printed circuit board 100, dimensions for the traces are often chosen to provide desirable electrical properties for the signal transmission paths. Two important electrical properties are impedance and cross-talk. Decreasing the distance between signal conductors results in increased cross talk.

The number of traces that may be formed on a layer may also depend on the accuracy of the manufacturing process used to form the printed circuit board. It is important that the selected dimensions for the signal traces result in a printed circuit board that may be reliably manufactured at a reasonable cost. Making signal traces too close together can increase the defect rate for manufactured printed circuit boards.

One way in which cross talk is reduced is by alternating the predominant direction of signal traces in adjacent layers. In the example of FIG. 1, printed circuit board 100 is shown with an X and Y direction. Pairs of traces 140₁, 140₂, 140₃, 142₁, 142₂, and 142₃ run in the X direction. Pairs of signal traces 150₁, 150₂, 152₁, and 152₂, run in the Y direction. By running the traces in adjacent layers in orthogonal directions, the amount of overlap between any two pairs of signal traces is minimized. Having only a small area of overlap reduces cross talk.

A reduction in cross talk may be achieved even if the signal traces are not perfectly orthogonal. Many printed circuit board design tools can be preprogrammed to limit the relative angular orientation between traces running on adjacent signal layers. A typical limit may specify that traces on adjacent layers run in directions that differ by at least 45 degrees.

FIG. 2 shows printed circuit board 100 in cross-sectional view. FIG. 2 shows that printed circuit board 100 may contain more layers than illustrated in FIG. 1. For example, printed circuit board 100 includes an additional core 212 acting as a spacer and a ground plane 214 adjacent to pairs of traces 152₁, and 152₂. In this view, pairs of traces such as 150₁, and 152₁ are shown running in the Y direction while pairs of traces such as 140₁, 140₂, 140₃, 142₁, 142₂, 142₃, are shown running in the X direction.

### SUMMARY OF INVENTION

In one aspect, the invention relates to a printed circuit board comprising a first signal layer and a second signal layer adjacent the first signal layer and a reference layer adjacent the first signal layer, each of the first signal layer and the second signal layer comprising a plurality of signal traces. A spacing between the first signal layer and the second signal layer is at least five times a spacing between the first signal layer and the reference layer. Also, traces of the second signal layer are disposed at an angle of less than 45 degrees relative to traces of the first signal layer.

In another aspect, the invention relates to a method of manufacturing a printed circuit board. The method includes forming a stack comprising a plurality of cores. Each of the cores has insulative material with at least a first surface and a second surface, thereby providing a plurality of surfaces within the stack. A first plurality of traces are on a first of the plurality of surfaces and a second plurality of traces are on a second of the plurality of surfaces. At least one ground plane is on a third of the plurality of surfaces. The first surface and the second surface are separated by insulative material of a first one of the plurality of cores and the first surface and the third surface are separated by insulative material of a second of the plurality of cores. The first of the plurality of cores has a thickness at least five times a thickness of the second of the plurality of cores. The cores in the stack are fused.

In a further aspect, the invention relates to a printed circuit board comprising a first signal layer and a second signal layer adjacent the first signal layer and a reference layer adjacent the first signal layer. Each of the first signal layer and the second signal layer comprises a plurality of signal traces. The printed circuit board has a first via and a second via formed therein. A spacing between the first signal layer and the second signal layer is at least five times a spacing between the first signal layer and the reference layer. Traces of the first signal layer and the second signal layer pass between the first via and the second via.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a partially cut away and partially exploded view of a printed circuit board as in the prior art;

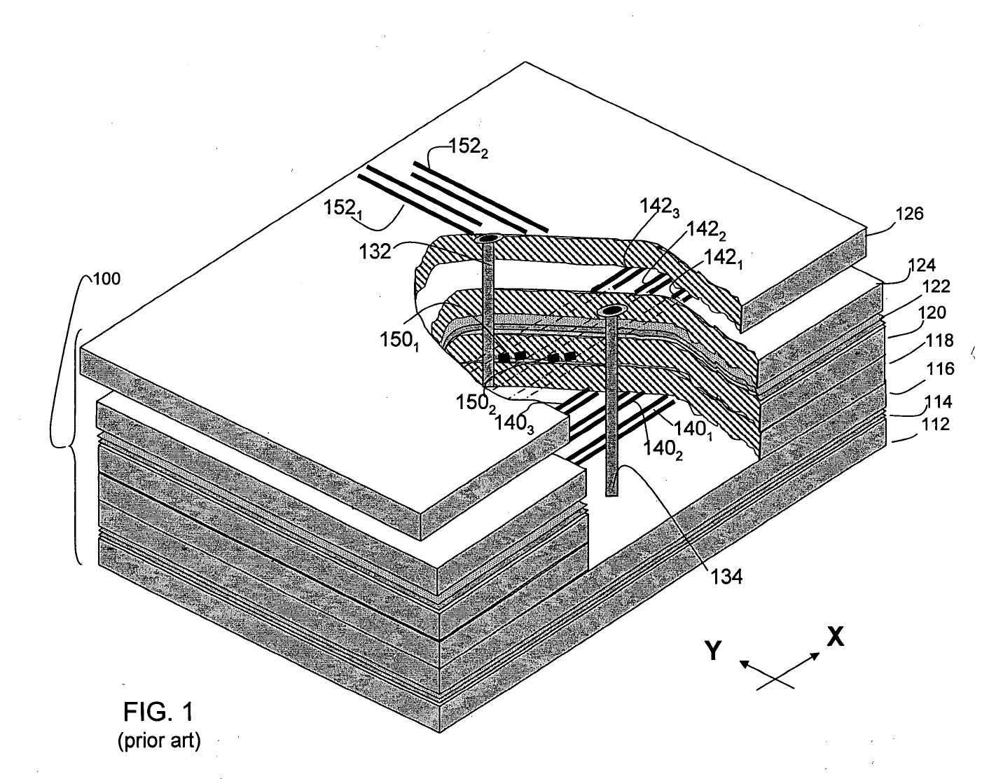

FIG. 2 is a cross-sectional view of the printed circuit board in FIG. 1; and

FIG. 3 is a cross-sectional view of a printed circuit board according to an embodiment of the invention.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

According to one aspect of the invention, the total number of layers required to carry all the signal traces in a printed circuit board may be reduced by increasing the spacing between selected layers of signal traces. By reducing the total number of layers, the number of manufacturing steps is reduced, thereby reducing the cost of manufacturing the printed circuit board.

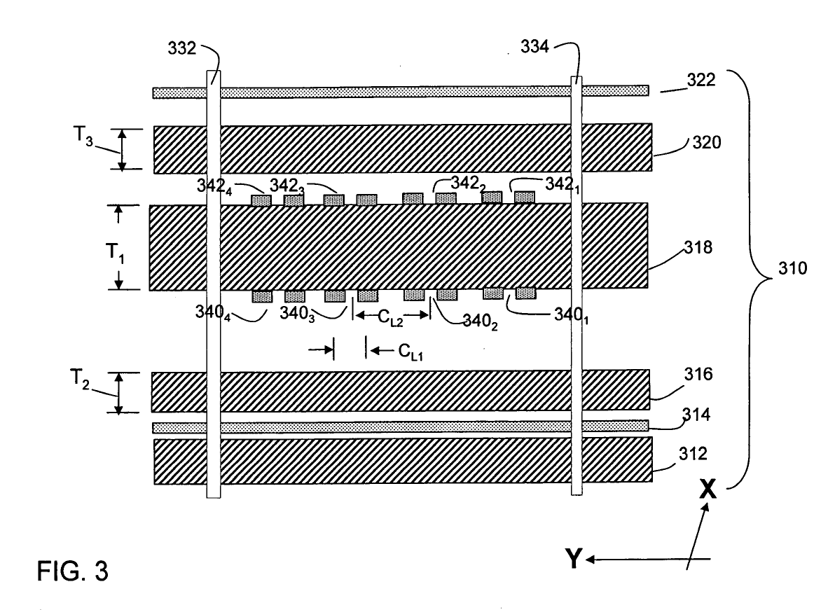

FIG. 3 shows a portion of a printed circuit board 310 in cross section. The portion of printed circuit board 310 illustrated in FIG. 3 is between vias 332 and 334. In many printed circuit boards, particularly backplanes, more signal traces must be routed in one direction than the other direction. For example, where printed circuit board 310 represents a backplane, many daughter cards may be connected to the backplane. The daughter cards may be connected at intervals in the X direction, requiring many signal traces to run in the X direction to interconnect daughter cards through the backplane.

To complicate routing in the X direction, connectors for each daughter card are mounted to the backplane using vias. Accordingly, the signal traces connecting daughter cards that are separated by intervening daughter cards must run between vias, such via as 332 and via 334, used to mount connectors for the intervening daughter cards.

The spacing between two adjacent vias creates a routing channel through which a limited number of signal traces may be routed on each layer of the printed circuit board. In a traditional printed circuit board design, once the routing channels on a layer carrying signal traces in the X direction are full, additional layers must be added to accommodate more traces, even if more traces could be routed on layers carrying traces in the Y direction. According to an embodiment of the invention, by selectively increasing the spacing between adjacent signal layers, no restriction need be placed on the orientation of traces in adjacent layers. Where more signal traces are required to run in one direction than the other, being able to route signal traces with the same orientation in adjacent layers reduces the total layer count of the printed circuit board.

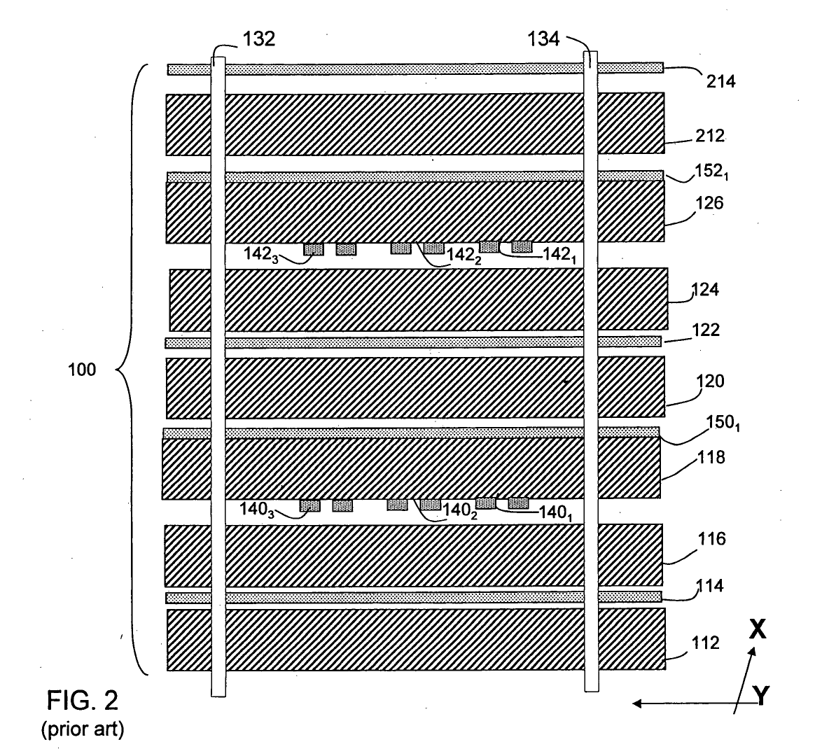

For example, FIG. 2 shows a total of seven layers required to route six pairs of signal traces in the routing channel between vias 132 and 134. In contrast, FIG. 3 shows only four layers used to route eight pairs of signal traces between vias 332 and 334. The increase in the number of traces is partially the result of dimensions that allow pairs of traces to be formed closer together. The increase in also the result of adjusting dimensions to allow adjacent signal layers to carry traces with the same orientation.

In manufacturing a printed circuit board, forming a pattern of conductive material on a core requires multiple process steps, each of which adds cost to the manufacturing process. Accordingly, there is a significant cost associated with each core containing one or more conductive layers. By reducing the total number of cores required to manufacture a printed circuit board, the cost of manufacture may be decreased.

FIG. 3 shows printed circuit board 310 containing a core 318. Core 318 includes pairs of traces 340₁, 340₂, 340₃ and 340₄ on the lower surface and pairs of traces 342₁, 342₂, 342₃ and 342₄ on the upper surface. The traces in each pair are shown to have an on-center spacing denoted C_{LI}. The on-center spacing between adjacent pairs is shown to be C_{L2}. In the pictured embodiment, each pair has the same spacing, but uniform spacing is not a limitation of the invention.

The matrix material separating the upper surface and lower surface of core 318 may be a material as is traditionally used in the manufacture of printed circuit boards, such as a fiberglass-filled epoxy.

In the pictured embodiment, neither core 316 nor core 320 contains a conductive layer. Core 316 and core 320 each separates signal traces on one layer from an adjacent ground plane. Core 316 separates pairs of signal traces 340₁, 340₂, 340₃ and 340₄ from ground plane 314.

Core 316 has a thickness T₂. In the illustrated embodiment, thickness T₂ is 10 mils (0.25 mm) or less. In some embodiments, thickness T₂ may be in the range of about 5-7 mils (0.13 to 0.17 mm). By reducing the thickness T₂ of core 316, electromagnetic radiation from each of the pairs of signal traces 340₁, 340₂, and 340₃ more strongly couples to ground. As a result, there is less coupling between the pairs of signal traces, thereby reducing cross talk caused by electromagnetic radiation from any of the pairs of signal traces 340₁, 340₂, 340₃ and 340₄. Because of the reduced levels of crosstalk, signal traces may be placed closer together without creating an unacceptable level of crosstalk.

Core 320 likewise separates pairs of signal traces 342₁, 342₂, 342₃ and 342₄ from an adjacent ground plane 322. Core 320 may have a thickness T₃, comparable to the thickness T₂ of core 316, but uniform thickness is not a limitation of the invention.

Reducing the thicknesses T₂ or T₃ allows adjacent pairs of signal traces on the same layer to be made closer together without unacceptably increasing the cross talk between pairs of signal traces on the same layer. In FIG. 3, adjacent pairs of signal traces are shown separated by a distance C_{L2}. In some embodiments, the distance C_{L2} may be about 20 mils or less. In the pictured embodiment, the distance C_{L2} is 14 mils (0.34 mm) or less.

FIG. 3 shows that four pairs of signal traces are routed in the channel between vias 132 and 134. More than four pairs may be routed per layer. For example, embodiments using conventional connector technology may result in vias 132 and 134 spaced to leave a routing channel sufficient to route five pairs of signal traces per layer.

Core 318 has a nominal thickness T₁ that is larger than the spacing between adjacent signal layers in a traditional printed circuit board. In the illustrated embodiment, thickness T₁ is greater than about 25 mils (0.6 mm). Increasing the thickness T₁ decreases the coupling between pairs of signal traces in adjacent layers, which are, in the embodiment of FIG. 3, formed on opposing surfaces of core 318. Decreasing coupling decreases crosstalk.

When the thickness T₁ is made sufficiently large, the restriction found in some prior art printed circuit board designs that the traces in adjacent layers of signal traces be routed with an orientation that differs by more than 45 degrees is not required. With printed circuit boards designed according to the exemplary embodiment, traces on adjacent layers of signal traces may be routed with orientations that differ by 45 degrees or less. In this example, the adjacent signal layers formed on both surfaces of core 318 are shown routed in the X direction. However, traces on each layer may be routed in any direction, including with multiple orientations on the same layer.

While various ranges of values may be selected for a specific design, in certain embodiments, thickness T₁ will be at least about five times thicknesses T₂ or T₃. In some embodiments, thickness T₁ will be approximately eight or ten times thicknesses T₂ or T₃, though even greater ratios are possible.

Also, in the described embodiment, the thickness T₁ is at least about three times distance C_{L2}. In other embodiments, the thickness T₁ is at least about four times distance C_{L}, though even greater ratios are possible.

Printed circuit board 310 may be formed using traditional processing techniques for printed circuit boards, whether now known or hereafter developed. Each of the cores illustrated in FIG. 3 may be formed of traditional matrix materials, whether now known or hereafter developed. Examples of a suitable material are thermoplastic materials, including fiberglass filled epoxy, such as material sold under the trade name FR4. The cores may be patterned and etched using traditional processing techniques, whether now known or hereafter developed to form the finished printed circuit board.

### EXAMPLE

A printed circuit board was manufactured using a core such as 318 having a thickness of approximately 60 mils (1.5 mm). Signal traces were formed of 0.5 ounce copper (approximately 0.6 mils (0.015 mm) thick) on each surface. Individual traces had a nominal width of 6 mils (0.16 mm) and traces within a pair had an edge-to-edge spacing of 7 mils (0.17 mm), resulting in an on-center spacing of 13 mils (0.32 mm) for signal traces within a pair. In this example, a nominal spacing of 6 mils (0.15 mm) was provided between each signal layer and an adjacent ground plane. Spacing between adjacent layers of signal conductors was nominally 60 mils (1.5 mm).

Ground planes were formed with 0.5 ounce copper. Each resulting pair of signal conductors had a nominal impedance of 100 ohms. Using standard printed circuit board processing techniques, this nominal impedance may be achieved with a tolerance of plus or minus 20 percent or less. In the example, the achieved tolerance was plus or minus about 10 percent.

With the spacing as described, pairs of signal traces were routed on each signal layer with no defined orientation. In the routing channels between vias used to attach electrical connectors to the printed circuit board, up to five pairs of signal conductors were routed per layer in the routing channels between vias used to mount connectors to the printed circuit board. Crosstalk was less than about −40 dB.

The structure illustrated in FIG. 3 showing four layers was duplicated in the printed circuit board constructed, resulting in an eight-layer printed circuit board. The thickness of core 312 in the illustrated embodiment does not impact the electrical properties of the pairs of signal conductors. Accordingly, the thickness of core 312 may be set to define the overall thickness of the printed circuit board 310. In this example, the thickness was adjusted to provide an overall board thickness of approximately 4.6 mm (0.19 inches). Manufacturing cost is estimated to be reduced by approximately 20% in comparison to a printed circuit board of equivalent performance formed using traditional design rules resulting in a 12 layer printed circuit board.

Having thus described several aspects of at least one embodiment of this invention, it is to be appreciated various alterations, modifications, and improvements will readily occur to those skilled in the art.

For example, the invention was illustrated in connection with a printed circuit board intended to be used as a backplane. The invention may be used in connection with any printed circuit board, regardless of intended application.

Also, the specific structure of the cores used to form a printed circuit board is not a limitation on the invention. For example, FIG. 3 shows that pairs of signal traces are formed on opposite surfaces of core 318. A similar printed circuit board 310 may be formed with a layer of signal traces on the lower surface of core 320 and a layer of signal traces in the upper surface of core 316 without any signal traces on core 318.

Also, the invention is illustrated in connection with a printed circuit board in which traces are routed in pairs, such as may be used to carry differential signals. However, traces that carry single ended signals may be used instead of or in addition to pairs of signal traces.

As another example, one or more cores used as spacers may be inserted in the stack-up used to manufacture a printed circuit board.

Further, it is described that the number of layers in a printed circuit board can be reduced by decreasing the spacing between signal traces and an adjacent ground plane to thereby allow the signal traces to be placed closer together, thereby requiring fewer layers to route all the traces. It was also described that increasing the separation between adjacent signal layers allows traces to be routed without imposing orientation restriction, which can also reduce the number of layers required. These techniques may be used either alone or in combination.

Such alterations, modifications, and improvements are intended to be part of this disclosure, and are intended to be within the spirit and scope of the invention. Accordingly, the foregoing description and drawings are by way of example only.

What is claimed is:

1. A printed circuit board comprising a first signal layer and a second signal layer adjacent the first signal layer and a reference layer adjacent the first signal layer, each of the first signal layer and the second signal layer comprising a plurality of signal traces, wherein:
a) a spacing between the first signal layer and the second signal layer is at least five times a spacing between the first signal layer and the reference layer; and
b) traces of the second signal layer are disposed at an angle of less than 45 degrees relative to traces of the first signal layer.

2. The printed circuit board of claim 1, wherein traces on the first signal layer and the second signal layer are disposed in pairs.

3. The printed circuit board of claim 2, wherein traces within a pair have an on-center spacing of about 0.4 mm (15 mils) or less.

4. The printed circuit board of claim 3, wherein adjacent pairs of traces have an on-center spacing of at least about 1 mm (40 mils).

5. The printed circuit board of claim 4, wherein:
a) the spacing between the first signal layer and the second signal layer is greater than about 0.6 mm (25 mils); and
b) the spacing between the first signal layer and the reference layer is less than about 0.25 mm (10 mils).

6. The printed circuit board of claim 1, additionally comprising a second reference layer adjacent the second signal layer.

7. The printed circuit board of claim 6, additionally comprising a third signal layer and a fourth signal layer adjacent the third signal layer and a third reference layer adjacent the third signal layer, each of the third signal layer and the fourth signal layer comprising a plurality of signal traces, wherein:
a) a spacing between the third signal layer and the fourth signal layer is at least five times a spacing between the third signal layer and the third reference layer; and
b) traces of the third and fourth signal layers are disposed at an angle of less than 45 degrees relative to traces of the first signal layer.

8. The printed circuit board of claim 6, wherein a spacing between the first signal layer and the second signal layer is at least eight times a spacing between the second signal layer and the second reference layer.

9. The printed circuit board of claim 1, wherein:
a) the spacing between the first signal layer and the second signal layer is greater than about 0.6 mm (25 mils); and
b) the spacing between the first signal layer and the reference layer is less than about 0.25 mm (10 mils).

10. A backplane assembly comprising:
a) the printed circuit board of claim 2; and
b) a plurality of vias in the printed circuit board, with routing channels formed between adjacent ones of the plurality of vias and at least four pairs of signal traces are disposed on each of the first signal layer and the second signal layer in the routing channels.

11. A method of manufacturing a printed circuit board comprising:
a) forming a stack comprising a plurality of cores, each of the cores comprising insulative material having at least a first surface and a second surface, thereby providing a plurality of surfaces within the stack, with at least a first plurality of traces on a first of the plurality of surfaces and a second plurality of traces on a second of the plurality of surfaces and at least one ground plane on a third of the plurality of surfaces, wherein the first surface and the second surface are separated by insulative material of a first one of the plurality of cores and the first surface and the third surface are separated by insulative material of a second of the plurality of cores and the first of the plurality of cores has a thickness at least five times a thickness of the second of the plurality of cores; and
b) fusing the plurality of cores in the stack.

12. The method of claim 11, wherein the insulative material of each of the plurality of cores comprises a thermoplastic material and fusing the plurality of cores in the stack comprises heating and pressing the stack.

13. The method of claim 11, wherein the first surface and the second surface are opposing sides of the first of the plurality of cores and the third surface is on the second of the plurality of cores.

14. The method of claim 13, wherein the first of the plurality of cores has a thickness at least eight times the thickness of the second of the plurality of cores.

15. The method of claim 14, wherein the first plurality of traces and the second plurality of traces are disposed in pairs.

16. A printed circuit board comprising a first signal layer and a second signal layer adjacent the first signal layer and a reference layer adjacent the first signal layer, each of the first signal layer and the second signal layer comprising a plurality of signal traces, the printed circuit board having a first via and a second via formed therein, wherein:
a) a spacing between the first signal layer and the second signal layer is at least five times a spacing between the first signal layer and the reference layer; and
b) traces of the first signal layer and the second signal layer pass between the first via and the second via.

17. The printed circuit board of claim 16, wherein traces on the first signal layer and the second signal layer are disposed in pairs.

18. The printed circuit board of claim 17, wherein traces in a pair have an on-center spacing of about 0.4 mm (15 mils) or less.

19. The printed circuit board of claim 18, wherein each of the pairs of signal traces has an impedance of about 100 ohms+/15%.

20. The printed circuit board of claim 17, wherein traces on the first signal layer and traces on the second signal layer form ten pairs between the first via and the second via.
